(19) United States
(12) Patent Application Publication
(10) Pub. No.: US 2008/0003750 A1
(43) Pub. Date: Jan. 3, 2008

(54) METHOD OF MANUFACTURING FLASH MEMORY DEVICE

(75) Inventors: Jum Soo Kim, Icheon-si (KR); Hee Hyun Chang, Seongnam-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/609,886

(22) Filed: Dec. 12, 2006

(30) Foreign Application Priority Data
Jun. 28, 2006 (KR) 2006-58746

(51) Int. Cl. H01L 21/336

(52) U.S. Cl. 438/266; 438/756; 438/770

(57) ABSTRACT

A method of manufacturing a non-volatile memory device includes providing a floating gate layer over a semiconductor substrate. The floating gate layer and the semiconductor substrate are etched to form a trench. An isolation structure is formed in the trench. An upper portion of the isolation structure is etched, wherein an upper sidewall of the floating gate layer is exposed by the etching of the upper portion of the isolation structure. An oxide layer is formed on the floating gate layer to round an upper corner of the floating gate layer. A control gate layer is formed over the floating gate layer.

### BACKGROUND OF THE INVENTION

The present invention relates to a flash memory device and, more particularly, to a method of manufacturing a flash memory device, in which Program/Erase (P/E) cycling endurance and data retention are improved by modifying the dielectric layer formed between the floating gate and the control gate.

In general, semiconductor memory devices are typically classified into volatile memory or non-volatile memory.

Volatile memory includes Random Access Memory (RAM), such as Dynamic RAM (DRAM) and Static RAM (SRAM). Volatile memory can input and retain data when being supplied with power, but the data becomes volatile and cannot be retained when power is cut off.

In the DRAM, the transistor is responsible for the switch function and the capacitor provides the data storage function. If power is not supplied, internal data within the DRAM is lost. The SRAM has a flip-flop type transistor structure. Internal data within the SRAM is also lost without continuous power.

In contrast, non-volatile memory, whose data is not lost when power is shut off, has been developed in large part for use in consumer electronics. Commercialized products of the non-volatile memory include Electrically Programmable Read Only Memory (EPROM), Electrically EPROM (EEPROM), flash memory, and so on. NAND flash memory has been in the spotlight correlating with an explosive growth of mobile communication devices, MP3 players, digital camera, etc.

FIG. 1 illustrates a general flash memory device. Referring to FIG. 1, a tunnel oxide layer 12 is formed on a semiconductor substrate 10 of active regions defined by field regions 11. A floating gate 13 is formed on the tunnel oxide layer 12. A dielectric layer 14 is formed on the entire surface including the floating gate 13. A control gate 15 is formed on the dielectric layer 14. The control gate 15 is used as a word line and generally includes a polycide structure in which a doped polysilicon layer 15a and a metal silicide layer 15b are laminated in order to lower the resistance value.

As shown in an upper right part of FIG. 1, the top edge of the floating gate 13 is sharp and the electric field (or E-field) becomes concentrated at the sharp edge of the floating gate 13. This degrades the characteristics of the dielectric layer 14, which lowers the P/E cycling endurance and data retention.

To improve the level of integration, it is necessary to reduce the thickness of the dielectric layer 14. As the thickness of the dielectric layer 14 is reduced the effects of the E-field concentration, caused by the sharp corner of the floating gate 13, becomes more prominent. This correlation between E-field concentration and dielectric layer 14 thickness makes it difficult to improve the level of integration due to the difficulty in reducing the thickness of the dielectric layer 14.

### SUMMARY OF THE INVENTION

According to an aspect of the present invention, there is provided a method of manufacturing a flash memory device including the steps of; laminating a tunnel oxide layer and a conductive layer for a floating gate on a semiconductor substrate; etching the conductive layer for the floating gate, the tunnel oxide layer and the semiconductor substrate to form trenches; forming isolation layers in the trenches; etching the isolation layers to a predetermined thickness to expose the upper side of the conductive layer; and forming an oxide layer on the exposed conductive layer for the floating gate by an oxidization process and rounding the top corner of the conductive layer for the floating gate.

The method may further include the steps of; stripping the oxide layer after the oxidization process; laminating a dielectric layer and a conductive layer for a control gate on the entire surface including the conductive layer for the floating gate; and patterning the conductive layer for the control gate, the dielectric layer, and the conductive layer for the floating gate to form a gate.

Furthermore, the method may further include the steps of; forming a nitride layer and an upper oxide layer on the oxide layer after the oxidization process; forming a dielectric layer having the oxide layer, the nitride layer and the upper oxide layer; forming a conductive layer for a control gate on the dielectric layer; and patterning the conductive layer for the control gate, the dielectric layer, and the conductive layer for the floating gate to form a gate.

In one embodiment, a method of manufacturing a non-volatile memory device includes providing a floating gate layer over a semiconductor substrate. The floating gate layer and the semiconductor substrate are etched to form a trench. An isolation structure is formed in the trench. An upper portion of the isolation structure is etched, wherein an upper sidewall of the floating gate layer is exposed by the etching of the upper portion of the isolation structure. An oxide layer is formed on the floating gate layer to round an upper corner of the floating gate layer. A control gate layer is formed over the floating gate layer.

In one embodiment, the upper corner of the floating gate layer is formed as a result of the etching-an-upper-portion-of-the-isolation-structure step, wherein the oxidization process employs either a dry oxidization process or a wet oxidization process. The forming of the isolation structure includes: providing an insulating layer over the floating gate layer and into the trench; and removing the insulating layer until the floating gate layer is exposed. An upper surface of the isolation structure is substantially flushed to an upper surface of the floating gate layer after the removing-the-insulating-layer step.

### BRIEF DESCRIPTION OF THE DRAWINGS

FIG. 1 illustrates a general flash memory device;

FIGS. 2A to 2D are cross-sectional views illustrating a method of manufacturing a flash memory device according to an embodiment of the present invention; and

FIG. 3 is a graph showing variation in the threshold voltage according to P/E cycling in the flash memory device for the prior art and the present invention.

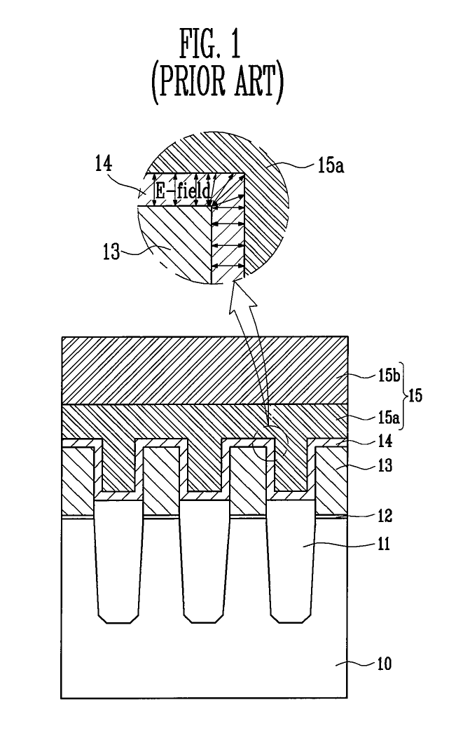

### DETAILED DESCRIPTION OF EMBODIMENTS

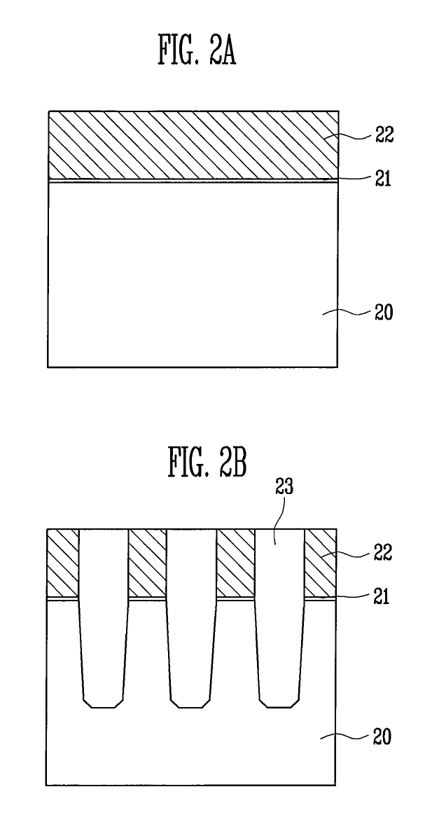

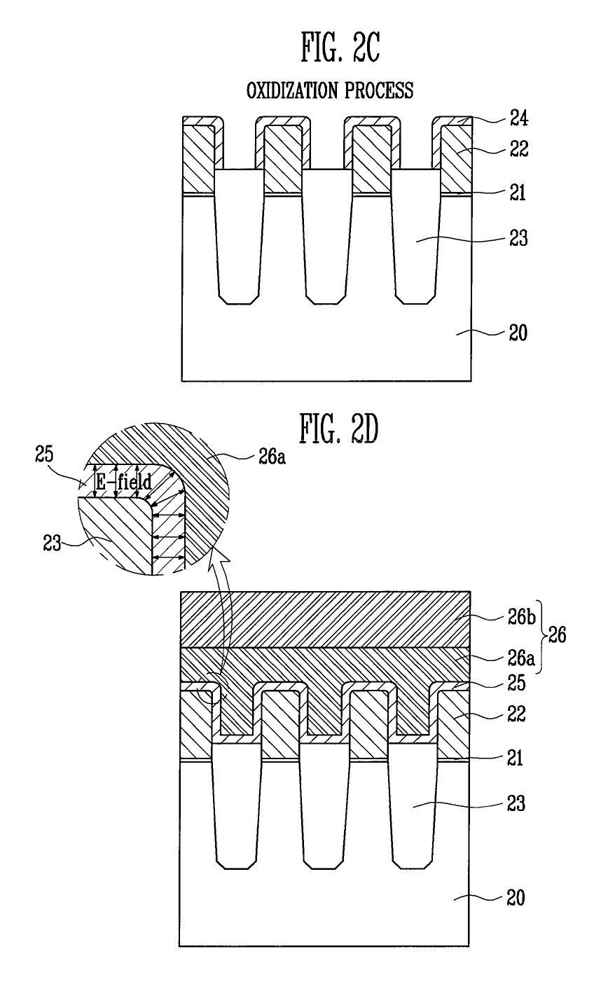

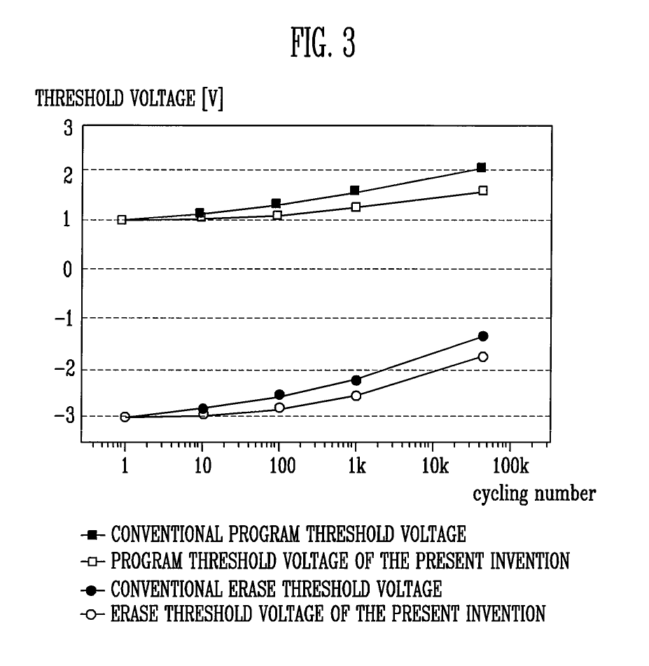

Referring to FIG. 2A, a tunnel oxide layer 21 (or tunnel dielectric layer) and a conductive layer 22 for a floating gate are sequentially formed on a semiconductor substrate 20. The conductive layer 22 is a polysilicon layer in the present implementation, but may be of a different layer in other implementations.

Referring to FIG. 2B, the conductive layer 22, the tunnel oxide layer 21 and the semiconductor substrate 20 of a predetermined region are etched to form trenches. An insulating layer (not shown) is formed over the substrate and provided in the trenches. The insulating layer is polished in such a way to expose the conductive layer 22, thereby forming isolation layers (or isolation structures) 23 in the trenches. The polishing process may employ CMP (Chemical Mechanical Polishing) or etch-back. In the present embodiment, the conductive layer 22 is a polysilicon layer, but may be of other conductive materials in other implementations.

Referring to FIG. 2C, to obtain the required coupling ratio, the isolation layers 23 are etched to a given thickness in order to lower the EFH (Effective Field Height). The etch process for the isolation layers 23 may be performed using a wet etch process or a dry etch process. As the isolation layer 23 is etched, the sides of the conductive layer 22 are exposed.

The conductive layer 22 is oxidized by an oxidization process. Accordingly, the top corners of the conductive layer 22, which have a right-angle, are rounded and an oxide layer 24 is also formed on the exposed surfaces of the conductive layer 22.

The oxidization process may employ either a dry oxidization process or a wet oxidization process. In the case where the dry oxidization process is employed, O₂ is used. In the case where the wet oxidization process is used, H₂O is used. In this embodiment the temperature of the oxidization process is set between 600 to 1000° C. and the oxidization process time is set within a range of 10 minutes to 1 hour. Furthermore, the thickness of the oxide layer 24 formed by the oxidization process is set within a range of 10 to 300 Å.

Referring to FIG. 2D, the oxide layer 24 is stripped. The oxide layer 24 can be stripped using BOE (Buffer Oxide Etch) and HF. In one implementation, the oxide layer 24 is stripped at the time the pre-cleaning process performed before the formation of the dielectric layer. If the oxide layer 24 is stripped during the pre-cleaning process, the manufacturing process is simplified since an additional process for stripping the oxide layer 24 need not be performed.

Though not shown in the drawings, if the oxidization process is controlled appropriately, the oxide layer 24 may be used as part of a dielectric layer (e.g., ONO or oxide-nitride-oxide layer) without stripping the oxide layer 24. For example, a nitride layer and an oxide layer may be formed on the oxide layer 24 to form a dielectric layer of an ONO (Oxide Nitride Oxide) structure.

Referring back to FIG. 2D, a dielectric layer 25 is formed over the conductive layer 22. The dielectric layer has an ONO structure in the present implementation but may be of a different configuration in other implementations. A conductive layer 26 for a control gate is formed over the dielectric layer 25. The conductive layer 26 may be formed using a lamination layer of a polysilicon layer 26a and a metal silicide layer 26b.

The conductive layer 26, the dielectric layer 25 and the conductive layer 22 are then patterned to form a gate. The flash memory device according to an embodiment of the present invention is thereby completed.

In the present embodiment, as shown in the right part of FIG. 2D, the edge of the conductive layer 22 is rounded. Therefore, while the program or erase function is carried out, the E-field is distributed more uniformly. Accordingly, the characteristics of the dielectric layer 25 can be improved, which leads to improved P/E cycling endurance and data retention characteristics.

Furthermore, the same characteristics can be obtained using a dielectric layer 25 having a thin thickness. Accordingly, the reduced thickness of the dielectric layer 25 can contribute to the improvement in the level of integration. In addition, the overall cell characteristics can be improved since variation occurring at the edge portion of the conductive layer 22 can be minimized.

From FIG. 3, it can be seen that in the prior art, as the P/E cycling number increases, the incremental increase in the threshold voltage of a device is large, whereas in the present invention, the incremental increase in the threshold voltage is small compared with the prior art. This is due to the rounded top edge of the conductive layer 22, which prevents the electric field from becoming concentrated.

As described above, the present embodiment has one or more the following advantages. First, the top corners of the floating gate are rounded by oxidizing the floating gate. It is therefore possible to prevent the E-field from becoming concentrated on the corners of the floating gate. Accordingly, the characteristic of the dielectric layer can be improved, therefore, P/E cycling endurance and data retention of a memory cell can be improved.

Second, the characteristics of the dielectric layer are improved and the thickness of the dielectric layer can be reduced. It is thus possible to increase the level of integration.

Although the foregoing description has been made with reference to the various embodiments, it is to be understood that changes and modifications of the present patent may be made by those skilled in the art without departing from the spirit and scope of the present patent and appended claims.

What is claimed is:

1. A method of manufacturing a non-volatile memory device, the method comprising:
providing a floating gate layer over a semiconductor substrate;
etching the floating gate layer and the semiconductor substrate to form a trench;
forming an isolation structure in the trench;
etching an upper portion of the isolation structure, wherein an upper sidewall of the floating gate layer is exposed by the etching of the upper portion of the isolation structure;
forming an oxide layer on the floating gate layer to round an upper corner of the floating gate layer; and
forming a control gate layer over the floating gate layer.

2. The method of claim 1, wherein the upper corner of the floating gate layer is formed as a result of the etching-an-upper-portion-of-the-isolation-structure step, wherein the oxidization process employs either a dry oxidization process or a wet oxidization process.

3. The method of claim 2, wherein in the case where the dry oxidization process uses O₂.

4. The method of claim 2, wherein in the case where the wet oxidization process uses H₂O.

5. The method of claim 1, wherein the oxide layer is formed at a temperature of 600 to 1000° C., in a process that lasts 10 minutes to 1 hour.

6. The method of claim 1, wherein the oxide layer has a thickness of 10 to 300 Å.

7. The method of claim 1, wherein the floating gate layer is a polysilicon layer.

8. The method of claim 1, wherein the isolation structure is etched to reduce the effective field height.

9. The method of claim 1, further comprising:
removing the oxide layer formed on the upper corner of the control gate layer;
forming a dielectric layer and the control gate layer over the floating gate layer; and
patterning the control gate layer, the dielectric layer, and the floating gate layer to form a gate structure for the non-volatile memory device.

10. The method of claim 9, wherein the oxide layer is removed at the time of a pre-cleaning process for the dielectric layer.

11. The method of claim 9, wherein the oxide layer is removed using BOE (Buffer Oxide Etchant) and HF.
